(19) United States
(12) Patent Application Publication
(10) Pub. No.: US 2014/0239972 A1
(43) Pub. Date: Aug. 28, 2014

(54) METHOD AND APPARATUS FOR MONITORING CONDITION OF A SPLICE

(71) Applicant: SmartKable, LLC, Elbridge, NY (US)

(72) Inventors: Douglas S. HIRSH, Skaneateles, NY (US); Michael M. MUEHLEMANN, Liverpool, NY (US)

(73) Assignee: SmartKable, LLC, Elbridge, NY (US)

(21) Appl. No.: 14/186,270

(22) Filed: Feb. 21, 2014

Related U.S. Application Data
(60) Provisional application No. 61/767,838, filed on Feb. 22, 2013.

(51) Int. Cl. G01R 31/04

(52) U.S. Cl. CPC G01R 31/04
USPC 324/538

(57) ABSTRACT

A splice monitoring apparatus and method of use is capable of determining splice characteristics by means of dynamic reactance through waveform shifts and harmonic distortions in comparison to a base frequency.

This application claims priority under 35 USC 119(e) based on provisional application No. 61/767,838, filed on Feb. 22, 2013, and which is incorporated herein in its entirety.

### FIELD OF INVENTION

The present invention relates to any joint that is spliced with similar or different materials that an electrical current can be passed through, verified, and analyzed using such techniques and monitored for attributes of degradation of the splice integrity.

### BACKGROUND ART

Connection points of transmission networks have been historically joined through a mechanical joint referred to as a splice. The joints are typically the “weak link” of any transmission network and presently there are limited methods in determining the splice characteristics after mechanically joining these components. After these splices are deployed, there is no easy means to determining the degradation of the joint from environmental elements or material break down. This degradation reduces electrical conductivity, increases transmission losses, and ultimately leads to catastrophic electrical and/or mechanical failure.

There is a need for technologies and/or products that can rapidly, accurately, and cost effectively characterize the condition of an installed splice to determine whether it should be repaired.

One such typical application that is in need of joint monitoring is the high voltage transmission network which made up of high tension lines, each of which is approximately ½ km in length. These individual lines are connected together by large mechanically crimped splices, and these splices are subject to degradation over long periods of service. Currently a majority of these splices are past their design life and inherently are the weak links with in the power distribution network, attributing to a great inefficiency of power transmission.

### SUMMARY OF THE INVENTION

The present invention provides an improved way to monitor joints for degradation, both from an apparatus standpoint and a method of monitoring.

The inventive method of monitoring a condition of a splice comprises establishing a baseline for a splice of defined construction in terms of phase shift and harmonic shift and then determining the phase shift and/or the harmonic shift for a splice that has been in service. The phase shift and/or the harmonic shift of the splice is compared with the baseline phase shift and harmonic shift. This comparison enables a determination to be made based on differences between the values of phase shift and/or the harmonic shift for the splice in service and the baseline values as to whether the splice in service is experiencing degradation and some action may be required to be taken.

The method can use one or both of the phase shift and harmonic shift to determine degradation. One exemplary standard to use is a difference greater than 10 degrees in phase shift as representative of degradation of the splice. Another standard could be to use a difference greater than 20 degrees in phase shift as an indicator that the splice needs to be replaced.

When using the harmonic shift, one exemplary standard could be a difference greater than 150% in a 3^{rd} or 5^{th} harmonic shift as representative of degradation of the splice. Yet another standard could be a difference greater than 200% in the 3^{rd} or 5^{th} harmonic shift as an indicator that the splice needs to be replaced.

While different techniques can be used to measure phase shift and harmonic shift as are known in the art, one way is to use instantaneous voltage potential across the splice and a current sense output of a transformer positioned downstream of the splice to measure phase shift and harmonic shift.

The invention also entails an apparatus adapted for practicing the method of the invention as described herein. The apparatus includes probes for determining instantaneous voltage potential across the splice and a current sense transformer for determining instantaneous current sense output based on the splice. Means are provided for determining the phase shift and harmonic distortion using the probes, the current sense transformer, the baseline for the phase and harmonic shifts to assess a condition of the splice.

### BRIEF DESCRIPTION OF THE DRAWINGS

FIG. 1 shows an example of transmission line splice and components of the invention for monitoring the condition of the splice.

FIG. 2 is a flow chart showing the processing of the voltage potential and current output from the components of FIG. 1.

FIG. 3 is a graph of normalized values against time for voltage and current values for one splice to depict a good splice condition.

FIG. 4 is a graph of normalized values against time for voltage and current values for another splice to depict a splice condition with more phase shift.

FIG. 5 is a graph of normalized values against time for voltage and current values for yet another splice to depict a splice condition with even more phase shift than FIG. 4.

### DETAILED DESCRIPTION OF THE INVENTION

The present invention provides an apparatus and method to monitor the condition of a splice in a transmission line and provide an alert that the splice is problematic.

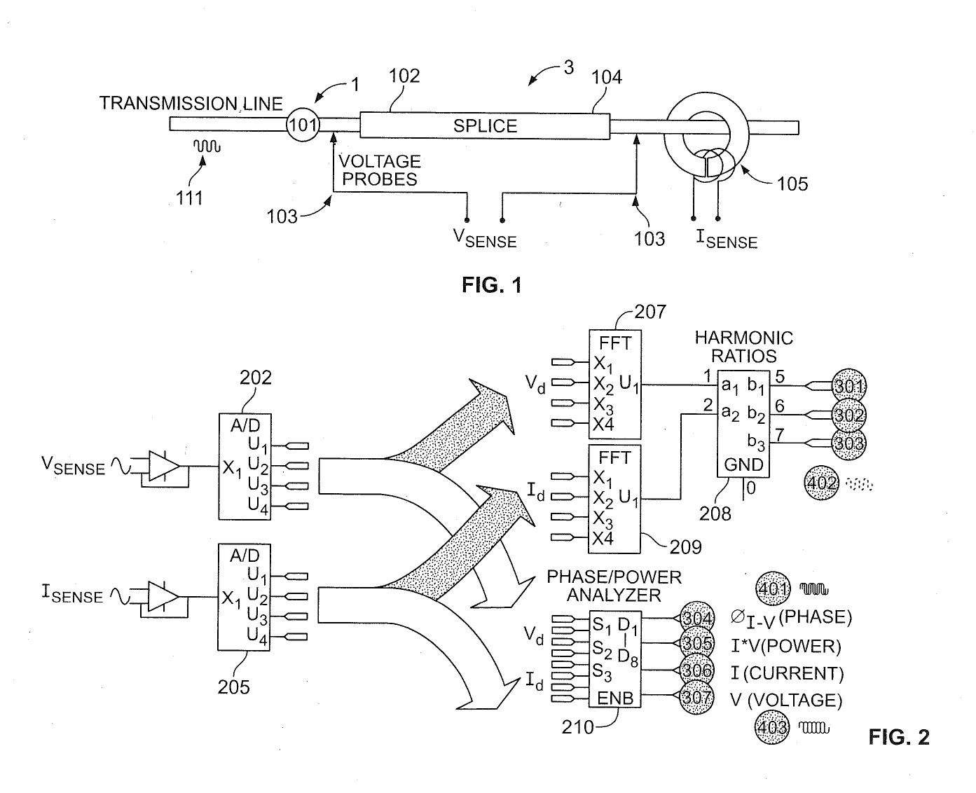

With reference to FIG. 1, a transmission line 1 and splice 3 are shown. An instantaneous electrical current 101 or potential 111 is either contained within the network or introduced for a specific time through transmission line 1 and the splice 3. Voltage probes 103 monitor the instantaneous voltage drop across the splice at points 102 and 104 of the splice 3, while a current sensing device (transformer or other device) 105 is configured to measure the instantaneous electrical current 101.

The instantaneous voltage potential across the splice points 102 and 104, and the instantaneous current sense output of transformer 105 are then processed for harmonic content and phase shift using either analog or digital methods. One way for this processing is shown in FIG. 2.

In a preferred embodiment, these signals Vₛₑₙₛₑ and Iₛₑₙₛₑ are processed through A/D converters 202 and 205. Then the digital output Vd and Id are filtered for harmonic analysis using either discrete hardware filters 207 and 209 or other frequency domain filters including discrete or continuous frequency domain algorithms processed by hardware, firmware, software or any hybrid combination of these methods as described below. The harmonic outputs or ratios are processed by a microprocessor 208 or other digital comparator hardware, analog comparator hardware, firmware, or software methods to complete the harmonic analysis. The above analysis methodology may also be accomplished by purely analog methods, or any combination of analog and digital methods which achieve the same or similar endpoints.

Still referring to FIG. 2 and in another embodiment, the instantaneous voltage potential across the splice 102 and 104, and the instantaneous current sense output of transformer 105 are processed through A/D converters 202 and 205 and the output Vd and Id are then analyzed for phase shift using either digital hardware 210 or analog methods. The above analysis methodology may also be accomplished by purely discrete analog hardware, or any combination of analog and digital methods which achieve the same or similar results.

Comparing the three outputs 301 to 303 from the hardware filters 207 and 209 and the four outputs 304-307 from the hardware 210 to the original electrical waveform 111 yields a phase shift 401, harmonic distortion 402 and time shift 403. These can be used to classify and quantify the deterioration characteristics of a splice or electrical joint. The original electrical waveform 111 can be generated by external means using standard waveform generating electronic equipment, or can be generated by the circuit itself during the standard operating conditions of the equipment as in the case of high tension wires operating at 50 or 60 Hz sinusoidal waveforms with current levels in the 1000 to 2000 amp range. This technique may be applied to any alternating signals, with or without DC offsets, including but not limited to waveforms that are sinusoidal, triangular, square, sawtooth, and all others including those with variable duty cycle.

The above description of FIGS. 1 and 2 describes means for determining the phase shift and harmonic distortion using probes that determine instantaneous voltage potential across the splice, and the current sense transformer that determines instantaneous current sense output based on the splice.

In order to show how the monitoring of the splice can show deterioration, a comparison was made using a splice of known good condition and two splices known to be deteriorated or defective.

Table 1 shows three splices, a good splice, splice #365, and splice #477, the latter two representative of the defective splices. Table 1 shows the voltage drop across the splice, the splice current, and the splice power loss.

TABLE 1
Total Power Loss across Splice

| | Good Splice | Splice #365 | Splice #477 |
|---|---|---|---|
| Voltage Drop (V_{RMS}) | 0.060 | 0.282 | 0.517 |
| Splice Current (A_{RMS}) | 771 | 711 | 467 |
| Splice Power Loss (W) | 46 | 201 | 241 |

From a simple resistive power loss calculation, it can be seen that the good splice is 4 to 5 times more efficient than the bad splices.

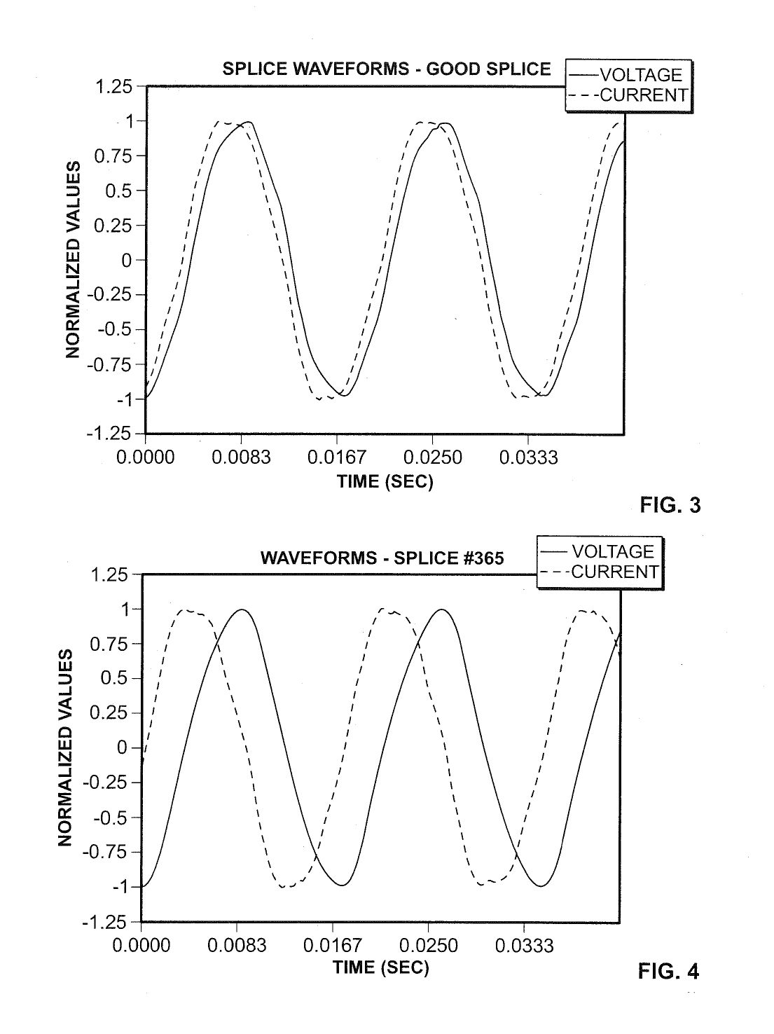

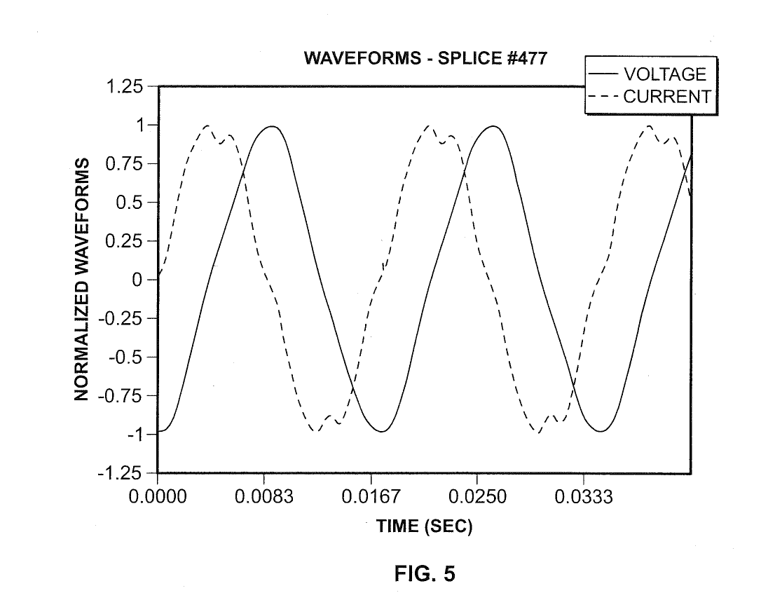

Next the normalized waveforms for each splice were compared to determine the amount of complex reactance exhibited. These are presented in FIGS. 3-5 and show the general nature of the quality of each waveform, and the lag between voltage and current that each splice induces. FIG. 3 depicts the waveform for the good splice and FIGS. 4 and 5 depict the waveform for the defective splice #365 and #477.

First, all splices experienced a phase shift as shown in FIGS. 3-5. However, the shift is greater for the two bad splices as compared with the good splice. To quantify this shift, the precise phase shift for each splice is tabulated in Table 2.

TABLE 2
Inductive Phase Shift

| | Good Splice | Splice #365 | Splice #477 |
|---|---|---|---|
| Time Lag (msec) | 0.64 | 3.24 | 3.92 |
| Phase Shift | 14 | 70 | 85 |
| Additional Phase Shift as | — | 56 | 71 |
| Compared to Good Splice | | | |

Table 2 suggests that inductive reactance may play a larger role in the general degradation losses observed in these splices. This is reasonable at high current conditions since even a slight deviation from a perfectly straight current flow through the splice will induce localized magnetic fields and induce eddy current heating. This also explains why simple resistive measurements are not especially accurate in predicting splice condition.

It can also be seen that the waveforms in FIGS. 3-5 are less than perfectly sinusoidal in character. To analyze the harmonic distortion, a real-time 1024 point FFT was performed on all the raw waveforms. This procedure provides a series of coefficients which represent the magnitude of the ripple at various frequencies in the waveform. From knowledge in the prior art, the focus is on the ratio of the 3^{rd} and 5^{th} harmonics with that of the known good sample. If the ratio of coefficients exceeds about 150% compared to the good splice, e.g., a “gold standard”, the ratios are sound indicators that corrosion exists between the metal current carrying conductors. The resulting harmonic data is given in Table 3.

TABLE 3
Fourier Transform Coefficients for Harmonic Analysis

| | Good Splice | | Splice #365 | | Splice #477 | |
|---|---|---|---|---|---|---|
| | Voltage | Current | Voltage | Current | Voltage | Current |
| 60 Hz Coefficient | 41 | 167 | 162 | 143 | 236 | 85 |
| (mV) | | | | | | |
| 180 Hz Coefficient | 2.169 | 9.78 | 8.643 | 6.796 | 12 | 1.87 |
| (mV) | | | | | | |
| 300 Hz Coefficient | 1.168 | 5.362 | 2.217 | 5.411 | 4.123 | 6.457 |
| (mV) | | | | | | |

For this analysis, one is looking for spectral deviation from the gold standard condition, which is the good splice. To perform this analysis, the coefficients to their primary (60 Hz) value are normalized and the results are in Table 4.

TABLE 4
Normalized Fourier Transform Coefficients for Harmonic Analysis

| | Good Splice | | Splice #365 | | Splice #477 | |
|---|---|---|---|---|---|---|
| | Voltage | Current | Voltage | Current | Voltage | Current |
| First Harmonic | 1 | 1 | 1 | 1 | 1 | 1 |
| Third Harmonic | 0.053 | 0.061 | 0.065 | 0.054 | 0.053 | 0.04 |
| Fifth Harmonic | 0.024 | 0.028 | 0.012 | 0.033 | 0.019 | 0.074 |

At first glance, this analysis does not appear to highlight the corrosive conditions that would be typically observed. The waveforms seem to have been altered, but not in the normal sense near the zero-crossings. Thus, further study was conducted to compare how the current and voltage waveforms were shifting with respect to one another, as compared to the shift exhibited in the good splice. To do this, the relative change was looked at by dividing the current by voltage coefficient (a Fourier conductance of sorts). The coefficients derived from Table 4. The results are shown in Table 5.

TABLE 5
Fourier Conductance Coefficients

| | Good Splice | Splice #365 | Splice #477 |
|---|---|---|---|
| 60 Hz Conductance Ratio | 1 | 1 | 1 |
| 180 Hz Conductance Ratio | 1.14 | 0.83 | 0.75 |
| 300 Hz Conductance Ratio | 1.17 | 2.79 | 3.91 |

These results are interesting in that they suggest a different form of harmonic distortion, one that produces an increasing departure of matching signal shape from the current and voltage curve within a given splice. In particular, the bad splices appear to deviate more at 5^{th} harmonic, and less in the 3^{rd} harmonic, as compared to a good splice. This can be clearly seen when the 3^{rd} and 5^{th} harmonic coefficients are normalized (see Table 6.)

TABLE 6
Fourier Conductance Coefficient Ratios

| | Good Splice | Splice #365 | Splice #477 |
|---|---|---|---|
| 60 Hz Conductance | — | — | — |
| Change Ratio | | | |
| 180 Hz Conductance | 1.00 | 0.72 | 0.65 |
| Change Ratio | | | |
| 300 Hz Conductance | 1.00 | 2.39 | 3.35 |
| Change Ratio | | | |

Because the non-linearity is affecting voltage and current differently, this could be explained by a non-linear inductive mechanism as the current is forced into different non-parallel channels when the various discrete current strands cross the splice. These non-parallel current paths would tend to set up small inductive regions, generating stray magnetic fields and internal eddy currents that would be providing the noted type of non-linear behavior.

The above data is compelling as a detection/characterization scheme. From this, it can be seen that any repeatable harmonic ratio above about 150% can provide a robust detection scheme. To verify that the above might be repeatable and therefore provide a robust detection method, additional tests were performed wherein the current introduction connection conditions were changed as much as possible to analyze differences in the current path through presumed good and bad sections of the splice. This is primarily due to the laboratory nature of the testing, i.e., the testing splices are no longer permanently connected to a high tension system.

The results are shown in Table 7. These results suggest that this might be another useful parameter in an attempt to try and assess the overall health and condition of an unknown splice.

TABLE 7
Variation in 5^{th} Harmonic Coefficient Ratios

| | Splice #365 | Splice #477 |
|---|---|---|
| Test #1 | 2.39 | 3.35 |
| Test #2 | 3.76 | 3.21 |

### Dynamic Reactance Analysis (For Detection of Complex Load Elements)

By analysis of the waveform at a preset frequency x₀ HZ against the voltage drop and current waveform through the splice to determine total dynamic reactance of the splice (total resistive, inductive and capacitive values) the condition of the splice can be determined from the phase delay, time variation, and harmonic distortion.

In a perfect splice, the load is purely resistive, and the magnitude of the resistance is very low. As the splice degrades, the magnitude of the resistive load may increase, and/or the load may become complex and therefore waveform shifts may be introduced. The complex load may introduce capacitive elements as dielectric elements are formed, or may introduce inductive components as currents are forced to move in the circumferential paths around higher resistance regions. By measuring the shift between voltage and current waveforms induced by the splice, the complete complex load elements within the splice provide a much more accurate and useful method for characterizing the splice.

The threshold for classifying splices and determining their “Percentage of Useful Life Remaining” (PULR) is arbitrarily set by the user and it based on the average values obtained by the manufacture for new splices. These baseline values will vary by manufacturer based on the design of the splice, the cable, and the mechanical methods of attachment.

For example, in some cases the high voltage line uses an iron core cable. In others applications, the line is constructed using only aluminum. In these two cases, the initial phase shifts for brand new splices will be different, and therefore the baseline for comparison must be appropriately adjusted. Similarly some crimping methods tend to introduce more circumferential circuit flow through the splice than others, again shifting the baseline for comparison with potentially degraded splices.

Once the appropriate baselines are established for a particular manufacturer's new splice (done via statistically significant product testing), a quantitative threshold may be established in order to compute the PULR for a particular unknown splice that is being characterized/monitored in the field.

In the preferred embodiment, any splice that exhibits a 3^{rd} or 5^{th} harmonic shift greater than 150% of that observed for a similar new splice is characteristic of a splice that has experienced degradation. Therefore, one measure of degradation would be the Percentage of Useful Life Remaining or PULR calculation that defines the PULR=50% when the harmonic shift reaches 150% of the as-new condition, and PULR=0% when the harmonic shift reaches 200%. A PULR of 0% means that the splice should be replaced at this time.

Similarly, in the preferred embodiment, the phase shift can be used to measure degradation in place of or in combination with the harmonic shift. Any splice that exhibits a phase shift that is greater than 20° than that observed for a similar new splice is characteristic of a splice that has experienced degradation. Therefore, a Percentage of Useful Life Remaining or PULR calculation is proposed that defines the PULR=50% when the phase shift reaches 10° more than that of the new splice, and PULR=0% when the phase shift reaches 20°. Again, a PULR of 0% means that the splice should be replaced.

The overall PULR will be defined as the minimum value determined by the above methods and will then be reported to the user.

As such, an invention has been disclosed in terms of preferred embodiments thereof which fulfills each and every one of the objects of the present invention as set forth above and provides a new and improved method and apparatus for monitoring and assessing the condition of a splice in a transmission line.

Of course, various changes, modifications and alterations from the teachings of the present invention may be contemplated by those skilled in the art without departing from the intended spirit and scope thereof. It is intended that the present invention only be limited by the terms of the appended claim.

I claim:

1. A method of monitoring a condition of a splice comprising:
a) establishing a baseline for a splice of defined construction in terms of phase shift and harmonic shift;
b) determining the phase shift and/or the harmonic shift for a splice that has been in service;
c) comparing the phase shift and/or the harmonic shift of step (b) with the baseline of step (a) to determine based on differences between the values of phase shift and/or the harmonic shift for the splice in service and the baseline values whether the splice in service is experiencing degradation.

2. The method of claim 1, wherein the phase shift is used to determine degradation.

3. The method of claim 1, wherein the harmonic shift is used to determine degradation.

4. The method of claim 2, wherein a difference greater than 10 degrees in phase shift is representative of degradation of the splice.

5. The method of claim 4, wherein a difference greater than 20 degrees in phase shift is an indicator that the splice needs to be replaced.

6. The method of claim 3, wherein a difference greater than 150% in a 3^{rd} or 5^{th} harmonic shift is representative of degradation of the splice.

7. The method of claim 6, wherein a difference greater than 200% in the 3^{rd} or 5^{th} harmonic shift is an indicator that the splice needs to be replaced.

8. The method of claim 1, wherein instantaneous voltage potential across the splice and a current sense output of a transformer positioned downstream of the splice are used to measure phase shift and harmonic shift.

9. An apparatus adapted for practicing the method of claim 1 comprising:
a) probes for determining instantaneous voltage potential across the splice,
b) a current sense transformer for determining instantaneous current sense output based on the splice, and
c) means for determining the phase shift and harmonic distortion using (a) and (b) to assess a condition of the splice.
